(19) United States
(12) Patent Application Publication
(10) Pub. No.: US 2008/0290507 A1
(43) Pub. Date: Nov. 27, 2008

(54) CHIP EMBEDDED PRINTED CIRCUIT BOARD AND FABRICATING METHOD THEREOF

(75) Inventors: Se Hoon Park, Seongnam-si (KR); Jun Chul Kim, Seongnam-si (KR); Jong Chul Park, Seoul (KR); Nam Kee Kang, Seoul (KR); Woo Sung Lee, Seongnam-si (KR); Chan Sei Yoo, Seongnam-si (KR)

Correspondence Address: LEE, HONG, DEGERMAN, KANG & WAIMEY, 660 S. FIGUEROA STREET, Suite 2300, LOS ANGELES, CA, 90017, US

(73) Assignee: Korea Electronics Technology Institute

(21) Appl. No.: 11/947,574

(22) Filed: Nov. 29, 2007

(30) Foreign Application Priority Data
May 23, 2007 (KR) 10-2007-0050202

(51) Int. Cl. H01L 23/36; H01L 21/58

(52) U.S. Cl. 257/717; 438/122; 257/E23.101; 257/E21.505

(57) ABSTRACT

The chip embedded printed circuit board and a fabricating method thereof are disclosed, wherein a circuit pattern is formed by depositing a metal layer on a support layer, a semiconductor chip is packaged on a support layer to wrap the semiconductor chip and the circuit pattern on the support layer and to form an isolation layer, a via hole filled with conductive material is formed through the isolation layer for interlayer electrical connection, part of the support layer is selectively removed to form a plated heat sink, such that a packaging process can be performed in a very planar state and the plated heat sink can be integrated with a printed circuit board.

### CROSS-REFERENCE TO RELATED APPLICATION

The present application is based on, and claims priority from, Korean Application Numbers 10-2007-0050202 filed May 23, 2007, the disclosure of which is incorporated herein by reference in its entirety.

### BACKGROUND

The following description relates generally to a chip embedded printed circuit board and a fabricating method thereof.

As electronic products are being made smaller and lighter, represented by the trends of smaller, thinner, higher-density, packaged, and portable products, so also is the multilayer printed circuit board (PCB) undergoing a trend towards finer patterns and smaller and packaged products. Accordingly, along with changes in the raw materials for forming fine patterns on the multilayer printed circuit board (PCB) and for improving reliability and design density (the number of chips mounted on a single circuit board or substrate), there is a change towards integrating the layer composition of circuits. Components are also undergoing a change from DIP (dual in-line package) types to SMT (surface mount technology) types, so that the mounting density is also being increased.

Generally, a method of packaging semiconductor chips on PCBs may include one or more of the following features. For example, a semiconductor chip may be stacked on the PCB, bonded and connected by a metal wire, or connected to the PCB using a flip chip bump.

Meanwhile, as functionality required by the electronic devices increases, an increased number of functional chips must be packaged on a limited space (or “real estate”) of the PCB, and this demand may suffer from a problem of causing the fabricated chip modules to be bulky as the thickness of the PCB is increased by thickness of semiconductor chips packaged to the PCB.

Flip chip PCBs are typically constructed with a 4-layer {1+2 (core)+1} structure or a 6-layer {2+2 (core)+2} structure. Usually, flip chip packaging places a high importance on flatness of substrate, such that thickness of a substrate for a core layer is approximately 400 μm. A semiconductor chip may be two dimensionally packaged on a surface of the PCB to have shocks on surroundings thereof and to create cracks on semiconductor chips due to differences of coefficient of thermal expansion with the PCB.

To solve or obviate these problems, chip embedded PCB technology has been researched where the semiconductor chips are embedded inside the PCB for integration there between. However, such embedding techniques bring about the following problems.
1. Difficulty in depositing high temperature fired high permittivity (dielectric constant) material on chip embedded PCBs. In other words, when the high temperature fired high permittivity material is deposited on a copper clad, co fired and deposited with polymer, a treatment problem occurs because the fabricating process is performed on the copper clad, and a bending problem is generated by differences of coefficient of thermal expansion with high permittivity material during high temperature firing.
2. Chips are embedded through build-up process using a substrate as a core for fabricating the chip-embedded PCBs, and in case of coreless substrate, it is difficult to manufacture the PCBs and to embed chips inside a two-layered substrate without core.
3. In case of many functional chips being embedded inside the PCB, a metal plated heat sink must be additionally formed to radiate the heat generated in the course of product use. Adhesive is used to adhere a plated heat sink to the substrate in manufacturing of conventional chip embedded PCBs during which substrates may be seriously compromised by generation of air bubbles, and the yield from manufacture of substrates may decrease significantly, thereby resulting in incurrence of additional manufacturing cost.

### SUMMARY

A fabricating method for chip embedded printed circuit board according to the present disclosure comprises: forming a circuit pattern on a support layer; packaging a high temperature fired high permittivity material on the support layer; packaging a semiconductor chip on the support layer, wrapping the semiconductor chip and forming an insulation layer; drilling the insulation layer for electrical connection to form a via hole; and selectively removing part of the support layer and using as a plated heat sink. According to the present inventive disclosure, a support layer of a sufficient thickness is used to enable a packaging process on a planar state, and the radiation plate may be integrally formed with the printed circuit board.

### BRIEF DESCRIPTION OF THE DRAWINGS

FIGS. 1a to 1h are cross-sectional views illustrating a fabricating method of chip embedded printed circuit board.

FIGS. 2a and 2b are schematic views illustrating forming a radiation plate following anodizing treatment of a support layer.

FIGS. 3a to 3e are schematic views illustrating a fabricating method of chip embedded printed circuit board according to another exemplary implementation.

FIG. 4 is a schematic view illustrating a state where plating current is made to flow through a support layer.

FIGS. 5a, 5b and 5c are cross-sectional views illustrating a fabricating method of chip embedded printed circuit board according to still another exemplary implementation.

FIG. 6 is a cross-sectional view illustrating a chip embedded printed circuit board according to an exemplary implementation.

FIG. 7 is a cross-sectional view illustrating a chip embedded printed circuit board according to another exemplary implementation.

### DETAILED DESCRIPTION

Now, exemplary implementations of the present inventive disclosure will be described in detail with reference to the accompanying drawings.

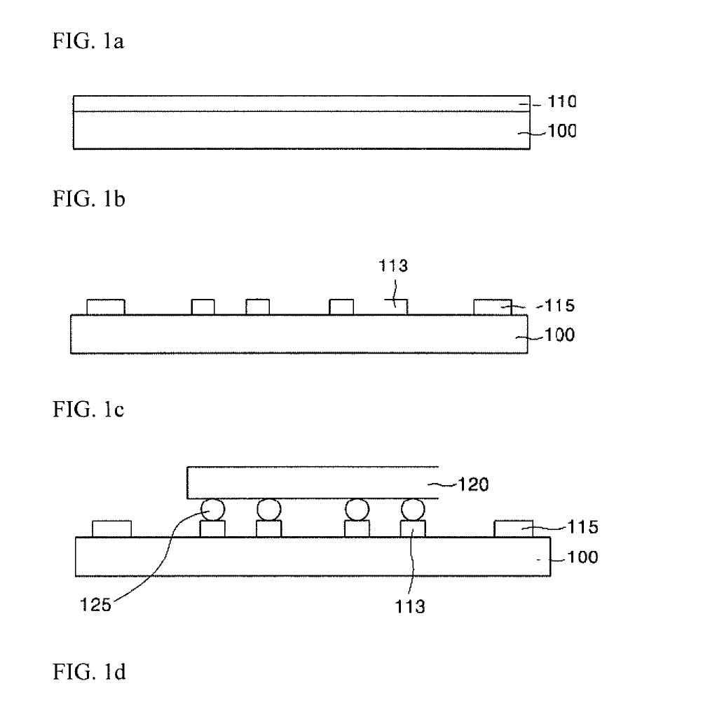

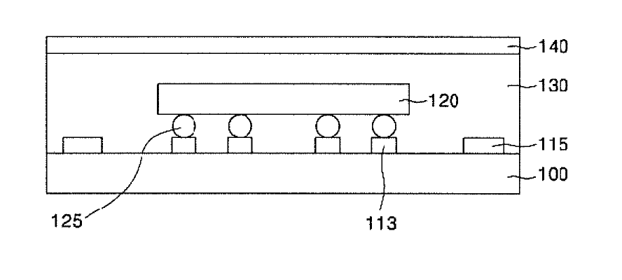

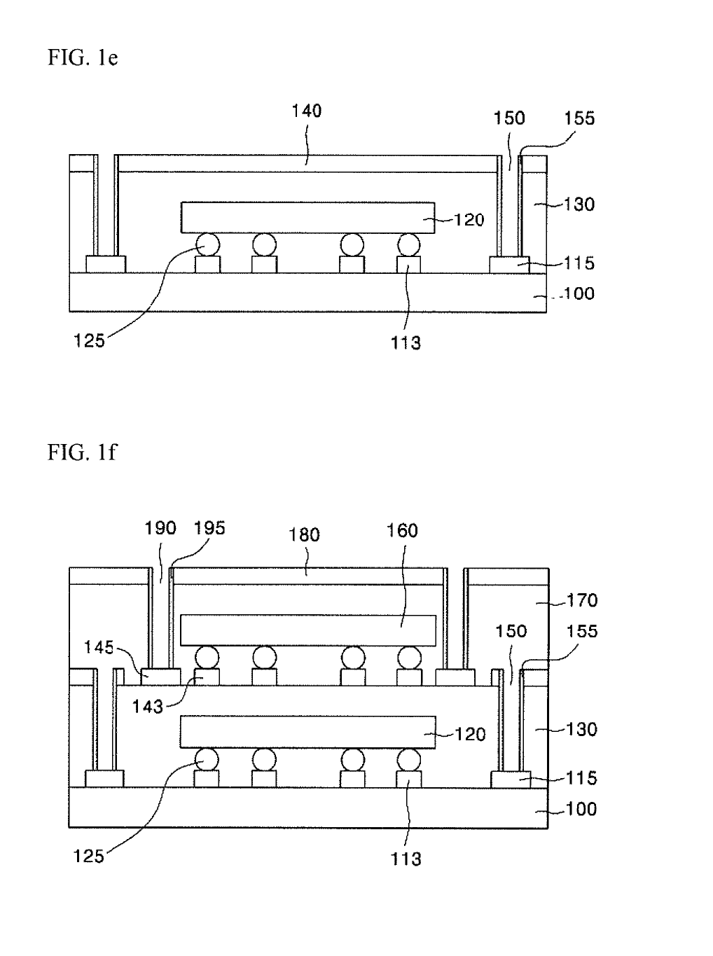

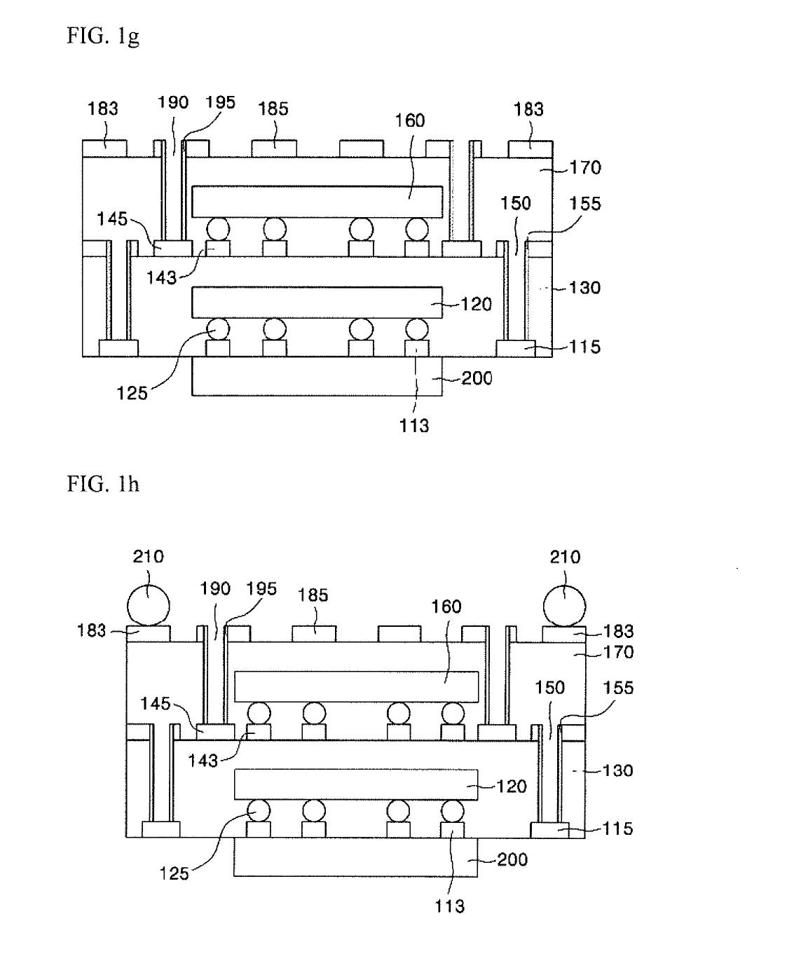

FIGS. 1a to 1h are cross-sectional views illustrating a fabricating method of chip embedded printed circuit board.

Referring to FIGS. 1a to 1h, a first metal layer (110) is formed on a support layer (100) (FIG. 1a). Examples satisfying the first metal layer (110) include, for example, Al, Au and Ag, and preferred among these is Al.

The support layer (100) preferably has a sufficient thickness of 500 μm˜2000 μm for providing a planar state in the fabricating method of chip embedded printed circuit board, and the first metal layer (110) is formed on the support layer (100) by deposition process or plating process.

Next, photolithography process is used to form a first bonding pad (113) and a first circuit pattern (115) on the support layer (100) (FIG. 1b). In other words, a photo resist is coated on the first metal layer (110), the photo resist is patterned, etching the first metal layer (110) by using the patterned photo resist as an etch mask to respectively form the first bonding pad (113) and the first circuit pattern (115) on the support layer (100). A coating process such as gold plating or OSP (Organic Solderability Preservation) coating process may be performed on the first bonding pad (113) and the first circuit pattern (115).

Furthermore, part of the first circuit pattern (115) may be deposited with high temperature fired (high temperature of 300° C. or more, mainly 300° C.˜1000° C.) permittivity material, and fired at a high temperature, and additionally formed with a metal layer to thereby embed a capacitor element inside the PCB.

As noted above, the high temperature fired permittivity material may be deposited using the metal support layer (100) instead of polymer-based substrate to easily treat the high permittivity material during co-firing and to prevent bending from occurring due to differences of coefficient of heat expansion with the high permittivity material.

Successively, a first semiconductor chip (120) is bonded to an upper surface of the first bonding pad (113) using flip-chip bonding method (FIG. 1c). In other words, a solder bump (125) formed underneath the first semiconductor chip (120) is so arranged as to be positioned on the first bonding pad (113), heat compressed and packaging the first semiconductor chip (120) onto the support layer (100).

Although an implementation using flip-chip bonding method for packaging the first semiconductor chip (120) onto the support layer (100) has been exemplified, other various methods such as, for example, wire bonding method and ACF (Anisotrofic Conductive Film) method may be employed.

Successively, the first circuit pattern (115) and the first semiconductor chip (120) on the support layer (100) may be wrapped to form a first isolation layer (130), and a second metal layer (140) is formed on the first isolation layer (130) (FIG. 1d).

The first isolation layer (130) is typically formed of a half-hardened prepreg, and the prepreg is typically made of glass fiber hardened by a predetermined heat and pressure and thermosetting resin.

A cavity may be formed about the first semiconductor chip (120) in order to prevent the first semiconductor chip (120) from being damaged when the first isolation layer (130) and the second metal layer (140) are stacked.

Next, a first via hole (150) is formed on the first circuit pattern (115) and a first plating layer (155) is formed on an inner wall of the first via hole (150) (FIG. 1e). The first via hole (150) may be formed by a mechanical drilling or laser drilling process, and the first plating layer (155) may be formed using electroless plating technique. The first via hole (150) and the first plating layer (155) are designed for interlayer electric connection. To this end, an inner wall of the first via hole (150) and an entire inner portion may be filled with conductive material.

Successively, a second bonding pad (143) and a second circuit pattern (145) may be formed on the first isolation layer (130) using the photolithographic process, and a second semiconductor chip (160) may be packaged using the flip-chip bonding method, a second isolation layer (170) and a third metal layer (180) are sequentially stacked on the first isolation layer (130), and a second via hole (190) and a second plating layer (195) are formed on the second circuit pattern (145) (FIG. 1f).

In other words, the processes from FIG. 1b to 1e may be repeated to package the second semiconductor chip (160) inside the PCB, and through these repeated processes, several semiconductor chips may be packaged, and the desired number of layers is stacked to form a multilayer PCB.

Now, a third bonding pad (183) and a third circuit pattern (185) are formed on the second isolation layer (170) using photolithographic process part of the support layer (100) is selectively removed to form a plated heat sink (200) (FIG. 1g).

In other words, a portion formed at a bottom surface of the first semiconductor chip (120) in the support layer (100) is left, while other remaining portions are removed to form the plated heat sink (200) underneath the first semiconductor chip (120). The integral formation of a plated heat sink with the PCB can dispense with an additive between the PCB and the plated heat sink to improve the heat dissipation characteristic, to make the process of separately bonding the plated heat sink unnecessary, and to thereby simplify the fabricating process.

Thereafter, a solder ball (210) is bonded onto the third bonding pad (183) for electrically connecting with the outside (FIG. 1h). At this time, the solder ball (210) may be bonded to a bonding pad of the uppermost layer of the PCB and a bonding pad of the lowermost layer of the PCB as well.

Meanwhile, in case aluminum is used for the support layer (100) in the forming process of the plated heat sink in FIG. 1g, the plated heat sink may be formed by an anodizing process.

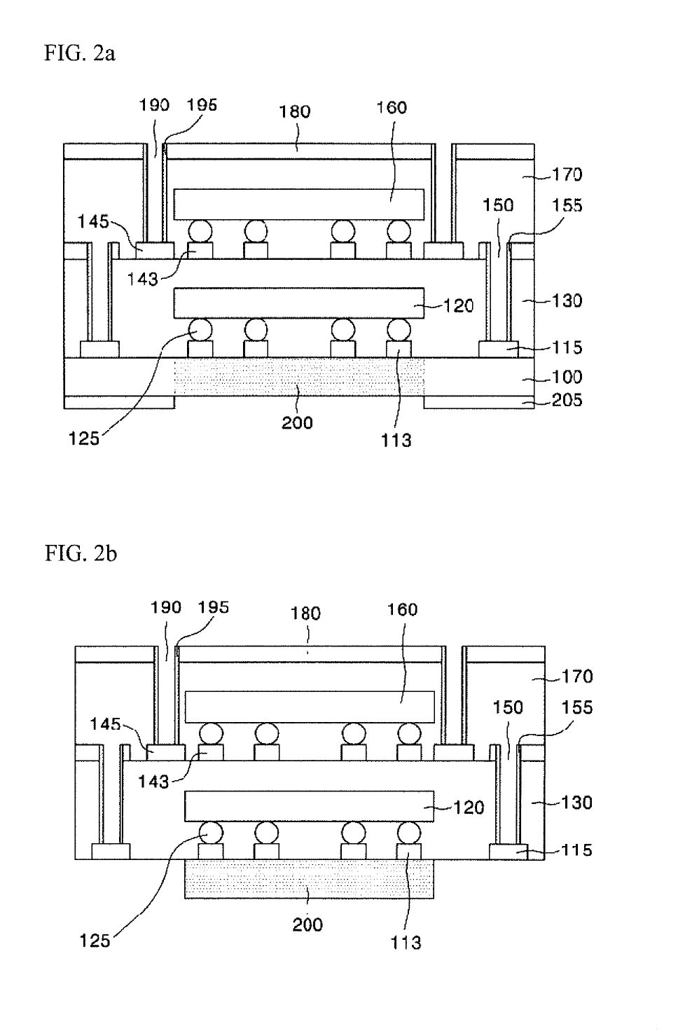

Referring to FIGS. 2a and 2b, a photo-resist (205) may be coated on the bottom surface of the aluminum support layer (100), the support layer (100) positioned underneath the first semiconductor chip (120) may be exposed, and an anodizing process may be performed to form Al₂O₃ (FIG. 2a).

Successively, when the remaining photo-resist (205) may be removed to etch the support layer (100) with aluminum etching solution, only an Al₂O₃ layer may remain to function as the heat sink (200) (FIG. 2b).

Although only the portion underneath the first semiconductor chip (120) in the support layer (100) may be anodized in the present exemplary implementation, an entire support layer (100) may be anodized for use as a heat sink.

According to the instant inventive concept, semiconductor chips may be embedded inside the PCBs up to a desired layer using a support layer, and the support layer may be selectively etched for use as a plated heat sink, thereby enabling to integrally form the plated heat sink with the PCB. Furthermore, a very planar packaging process may be performed due to sufficiently thick support layer, such that there is no need of a thick core layer like that of the conventional flip chip PCB.

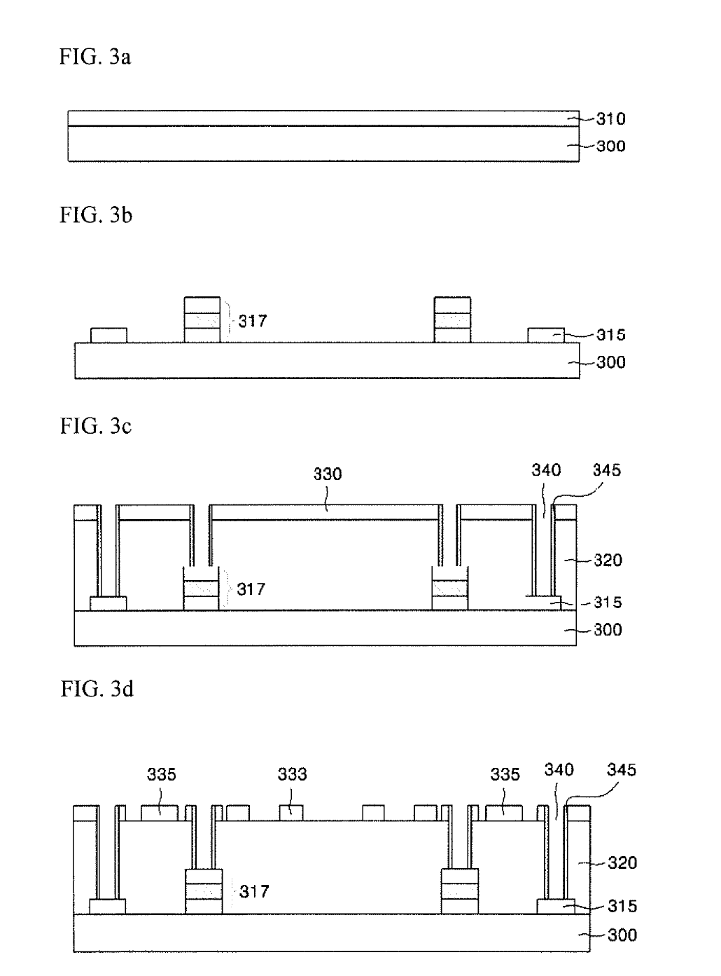

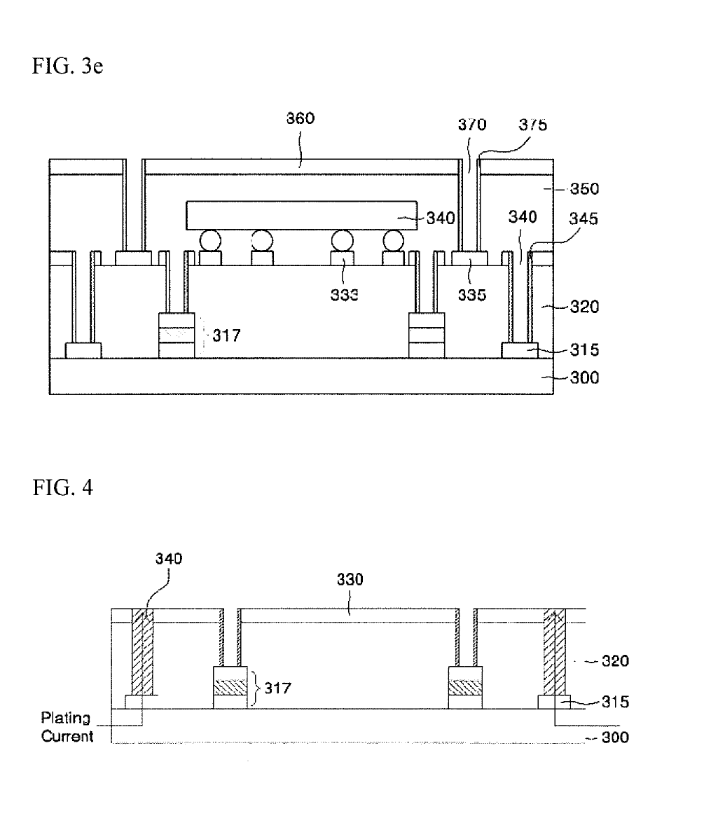

FIGS. 3a to 3e are schematic views illustrating a fabricating method of chip embedded printed circuit board according to another exemplary implementation.

Now, referring to FIG. 3a, a first metal layer (310) may be formed on a support layer (300).

Successively, a first circuit pattern (315) may be formed on the support layer (300) using the photolithographic process, a high temperature fired high permittivity material may be deposited on part of the first circuit pattern (315) and fired at a high temperature to form a capacitor element (FIG. 3b).

Thereafter, the first circuit pattern (315) and the capacitor element (317) on the support layer (300) may be wrapped to sequentially form a first isolation layer (320) and a second metal layer (330) via a thermal lamination, a first via hole (340) may be formed on the first circuit pattern (315) and the capacitor element (317), and a first plating layer (345) may be formed inside the first via hole (340) (FIG. 3c).

Successively, a second circuit pattern (335) and a bonding pad (333) may be formed on the first isolation layer (320) using the photolithographic process (FIG. 3d). Then, the semiconductor chip (340) may be flip-chip bonded on the bonding pad (333), the second circuit pattern (335) and the semiconductor chip (340) may be wrapped on the first isolation layer (320) to sequentially form a second isolation layer (350) and the third metal layer (360), and a second via hole (370) may be formed on the second circuit pattern (335) to form a second plating layer (375) inside the second via hole (370) (FIG. 3e).

Thereafter, part of the support layer (300) may be selectively etched for use as a plated heat sink to integrally form the PCB with the plated heat sink.

The present implementation has shown a case where semiconductor chips are packaged from a second layer instead of a first layer in a multilayer PCB, and besides this implementation, other various methods may be employed to package the semiconductor chips.

Meanwhile, in FIG. 3e, the first via hole (340) may be formed to cause an entire inner area of the first via hole (340) to be filled with conductive material, and at this time, if plating current is made to flow through the support layer (300), the first via hole (340) may be filled with conductive material dispensing with a separate seed layer, and in this case, heat may be dissipated through the first via hole (340) filled with the conductive material to thereby improve the heat dissipation effect.

In other words, as shown in FIG. 4, if the plating current is made to flow through the support layer (300) when the first via hole (340) formed on the first circuit pattern (313) is filled with the conductive material, the conductive material may be filled in the first via hole (340) perpendicular to the first circuit pattern (313) to dispel a fear of generating air bubbles and to enhance the heat extraction effect of the PCB.

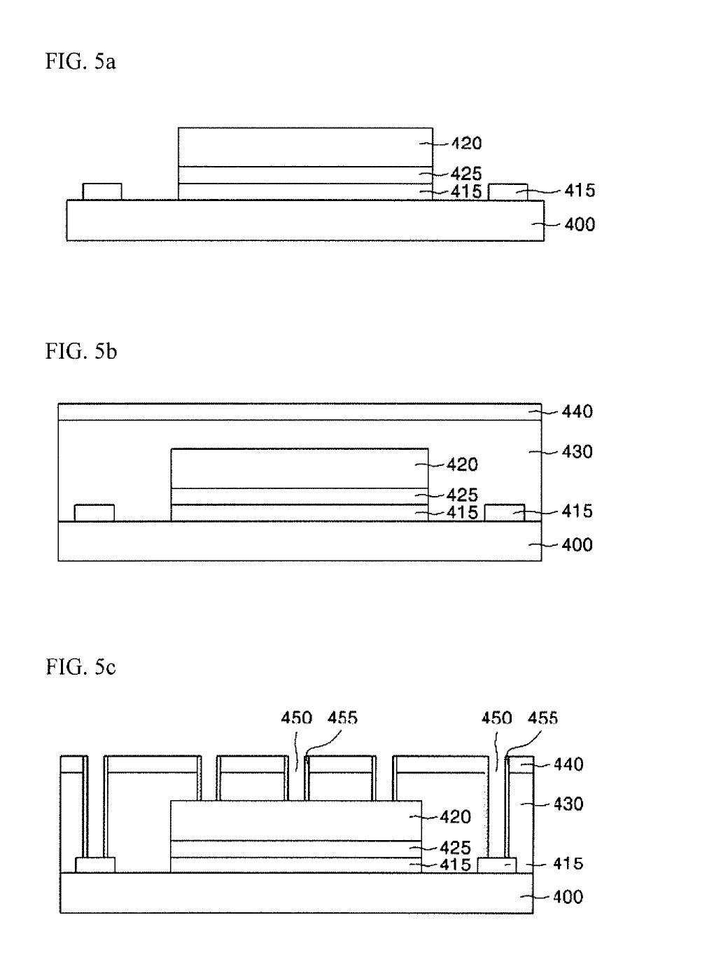

FIGS. 5a, 5b and 5c are cross-sectional views illustrating a fabricating method of chip embedded printed circuit board according to still another exemplary implementation.

Referring to FIGS. 5a, 5b and 5c, a method is disclosed wherein a semiconductor chip may be bonded to a PCB using epoxy instead of wire bonding or flip chip bonding method when semiconductor chip is packaged to the PCB, a via hole may be formed at a portion of a circuit pattern on the semiconductor chip to form a plating layer and then the semiconductor chip may be electrically connected to the PCB.

First, a support layer (400) may be formed thereon with a circuit pattern (415) and a semiconductor chip (420) may be bonded to the circuit pattern (415) using epoxy (425) (FIG. 5a).

Next, the first circuit pattern (415) and the semiconductor chip (420) on the support layer (400) may be wrapped to form an isolation layer (430), and a second metal layer (440) may be formed on the isolation layer (430) (FIG. 5b).

Successively, a via hole (450) may be formed on a circuit pattern (not shown) on the circuit pattern (415) and the semiconductor chip (420) of the support layer (400), and a plating layer (455) may be formed at an inner wall of the via hole (450) to electrically connect the semiconductor chip (420) to the PCB (FIG. 5c).

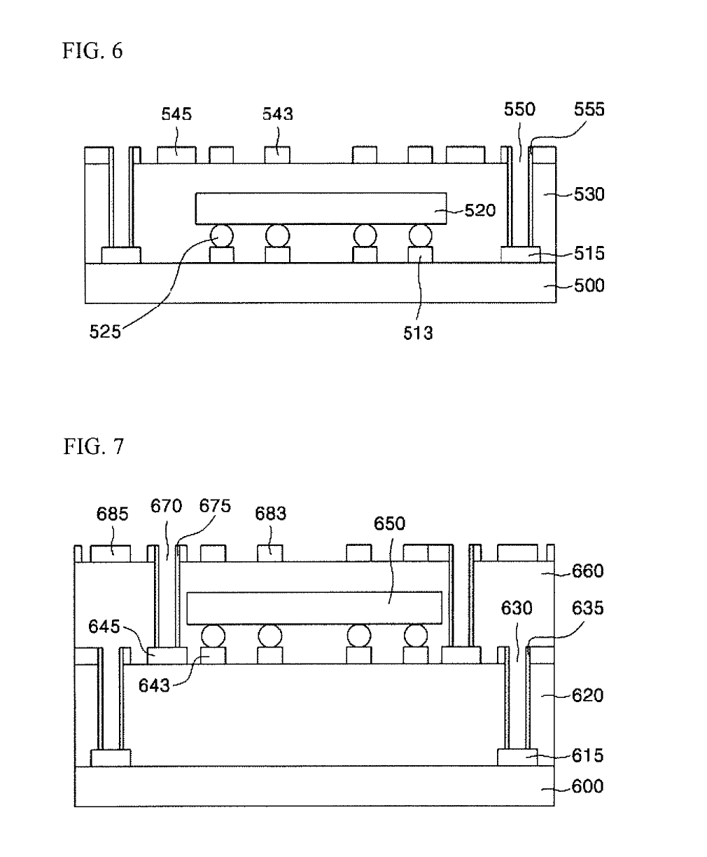

FIG. 6 is a cross-sectional view illustrating a chip embedded printed circuit board according to an exemplary implementation.

Referring to FIG. 6, a support layer (500) is formed thereon with a first bonding pad (513) and a first circuit pattern (515), and the first bonding pad (513) may be bonded to a semiconductor chip (520). And an insulation layer (530) is formed wrapping the first circuit pattern (515) and the semiconductor chip (520). The first circuit pattern (515) is formed thereon with a via hole (550) through the insulation layer (530). And inner wall of the via hole (550) is formed with a plating layer (555), and is formed thereon with a second bonding pad (543) and a second circuit pattern (545).

The support layer (500) functions as a plated heat sink for discharging outside the heat generated by the semiconductor chip (520). The support layer (500) therefore may be comprised of any one of the conductivity excellent metals consisting of, for example, Al, Au and Ag. The support layer (500) preferably has a thickness in the range of 500 μm˜2000 μm and may be formed underneath the semiconductor chip (520).

Furthermore, the support layer (500) may be further formed thereon with a capacitor made of high temperature fired high permittivity material, and may be further formed with a solder ball on the second circuit pattern (545).

FIG. 7 is a cross-sectional view illustrating a chip embedded printed circuit board according to another exemplary implementation.

Referring to FIG. 7, a support layer (600) may be formed thereon with a first circuit pattern (615), and a first isolation layer (620) may be formed on the support layer (600) to surround the first circuit pattern (615), and a second circuit pattern (645) and a first bonding pad (643) may be formed on the first isolation layer (620). A first via hole (630) may be formed on the first circuit pattern (615) through the first isolation layer (620) and the second circuit pattern (645), and a first plating layer (635) may be formed at an inner wall of the first via hole (630). A semiconductor chip (650) is bonded to the first bonding pad (643) to form a second isolation layer (660), surrounding the second circuit pattern (645) and the semiconductor chip (650). A second via hole (670) may be formed on the second circuit pattern (645) through the second isolation layer (660), and a second plating layer (675) is formed at an inner wall of the second via hole (670). The second isolation layer (660) is formed thereon with a third circuit pattern (685) and a second bonding pad (683).

As apparent from the foregoing, a sufficiently thick support layer can be employed to perform a packaging process on a planar state to stably treat a PCB during fabrication process. A semiconductor chip can be embedded inside the PCB to a desired layer using the support layer, and the support layer can be selectively etched for use as a plated heat sink to integrate the plated heat sink to the PCB.

Furthermore, a metal support layer instead of polymer-based substrate can be used to deposit a high temperature fired high permittivity material, such that the high temperature fired high permittivity material can be easily treated to thereby prevent a bending from generating due to differences of heat expansion coefficient with the high permittivity material.

Still furthermore, a plated heat sink can be integrally formed with the PCB, and there is no need of additive between the PCB and the plated heat sink to enable to enhance the heat dissipation feature, and as no separate process of bonding the plated heat sink is needed to enable to simplify the manufacturing process.

As the present disclosure may be embodied in several forms without departing from the spirit or essential characteristics thereof it should also be understood that the above-described implementations are not limited by any of the details of the foregoing description, unless otherwise specified, but rather should be construed broadly within its spirit and scope as defined in the appended claims, and therefore it will be understood by those of ordinary skill in the art that all changes and modifications that fall within the metes and bounds of the claims, or equivalents of such metes and bounds are therefore intended to be embraced by the appended claims.

What is claimed is:

1. A fabricating method for chip embedded printed circuit board comprising: forming a first circuit pattern on a support layer; packaging a semiconductor chip on the first circuit pattern; and forming an isolation layer on the support layer surrounding the first circuit pattern and the semiconductor chip, and forming a metal layer on the isolation layer.

2. The method as claimed in claim 1, comprising, following the formation of the metal layer, forming a via hole on the first circuit pattern through the isolation layer and the metal layer; etching the metal layer to form a second circuit pattern on the isolation layer; and
removing a region of the support layer except for a region underneath the semiconductor chip to form a plated heat sink.

3. The method as claimed in claim 2, wherein the support layer is made of aluminum.

4. The method as claimed in claim 3, wherein the step of forming the plated heat sink comprises: forming a photo-resist layer underneath the support layer; patterning the photo-resist layer to expose the support layer disposed underneath the semiconductor layer; anodizing the exposed support layer; and removing the photo-resist layer, etching and removing the support layer that is not anodized.

5. The method as claimed in claim 1, wherein the step of packaging the semiconductor chip is performed by a wire bonding or a flip chip bonding method.

6. The method as claimed in claim 1, further comprising forming a capacitor on the support layer using a permittivity material that is fired in the temperature range of 300° C.˜1000° C.

7. The method as claimed in claim 1, wherein the support layer is made of any one metal selected from Al, Au and Ag.

8. A fabricating method for chip embedded printed circuit board comprising: forming a first circuit pattern on a support layer; forming a first isolation layer on the support layer wrapping the first circuit pattern and forming a first metal layer on the first isolation layer; forming a via hole on the first circuit pattern through the first isolation layer and the first metal layer and forming a first plating layer at an inner wall of the first via hole; etching the first metal layer to form a second circuit pattern on the first isolation layer; and packaging a semiconductor chip in the first isolation layer.

9. The method as claimed in claim 8, wherein, following the step of packaging the semiconductor chip, forming a second isolation layer on the first isolation layer wrapping the second circuit pattern and the semiconductor chip, and forming a second metal layer on the second isolation layer; forming a second via hole on the second circuit pattern through the second isolation layer and the second metal layer, and forming a second plating layer at an inner wall of the second via hole; etching the second metal layer to form a third circuit pattern on the second isolation layer; and removing a region of the support layer except for a region underneath the semiconductor chip to form a plated heat sink.

10. The method as claimed in claim 9, wherein the support layer is made of aluminum

11. The method as claimed in claim 10, wherein the step of forming the plated heat sink comprises: forming a plated heat sink; forming a photo-resist layer underneath the support layer; patternizing the photo-resist layer to expose the support layer disposed underneath the semiconductor chip; anodizing the exposed support layer; and removing the photo-resist layer to etch and remove the support layer that is not anodized.

12. The method as claimed in claim 8 wherein the step of packaging the semiconductor chip is performed by a wire bonding or a flip chip bonding method.

13. The method as claimed in claim 8, further comprising using a permittivity material that is fired under a temperature range of 300° C.˜1000° C. to form a capacitor on the support layer following the formation of the first circuit pattern on the support layer.

14. The method as claimed in claim 8, wherein the support layer is made of any one metal selected from Al, Au and Ag.

15. A chip embedded printed circuit board (PCB) wherein a circuit pattern is formed on a plated heat sink, a semiconductor chip is packaged on the circuit pattern, an isolation layer is formed on the plated heat sink wrapping the circuit pattern and the semiconductor chip, a metal layer is formed on the isolation layer, a via hole is formed on the circuit pattern through the isolation layer and the metal layer, and a plating layer is formed at an inner wall of the via hole.

16. The PCB as claimed in claim 15, wherein the plated heat sink is made of any one metal selected from Al, Al₂O₃, Au and Ag.

17. The PCB as claimed in claim 15, wherein the plated heat sink has a thickness in the range of 500 μm˜2000 μm.

18. A chip embedded printed circuit board wherein a first circuit pattern is formed on a plated heat sink, a first isolation layer is formed on the plated heat sink wrapping the first isolation layer, a second circuit pattern is formed on the first isolation layer, a via hole is formed on the first circuit pattern through the first isolation layer and the second circuit pattern, a first plating layer if formed at an inner wall of the first via hole, a semiconductor chip is packaged on the first isolation layer, a second isolation layer is formed on the first isolation layer wrapping the second circuit pattern and the semiconductor chip; a metal layer is formed on the second isolation layer, a second via hole is formed on the second circuit pattern through the second isolation layer and the metal layer, and a second plating layer is formed at an inner wall of the second via hole.

19. The PCB as claimed in claim 18, wherein the plated heat sink is made of any one metal selected from Al, Al₂O₃, Au and Ag.

20. The PCB as claimed in claim 18, wherein the plated heat sink has a thickness in the range of 500 μm˜2000 μm.
